(19) United States
(12) Patent Application Publication
(10) Pub. No.: US 2015/0187915 A1
(43) Pub. Date: Jul. 2, 2015

(54) METHOD FOR FABRICATING FIN TYPE TRANSISTOR

(71) Applicant: Samsung Electronics Co., Ltd., Suwon-si (KR)

(72) Inventors: Hyung-Jun Joo, Yongin-si (KR); Byong-Kuk Kim, Seoul (KR); Ho-Gi Song, Yongin-si (KR); Young-Byeong Joo, Hwaseong-si (KR); Samuel Lee, Hwaseong-si (KR); Seung-Gi Hong, Yongin-si (KR)

(21) Appl. No.: 14/322,014

(22) Filed: Jul. 2, 2014

Related U.S. Application Data
(60) Provisional application No. 61/920,871, filed on Dec. 26, 2013.

(30) Foreign Application Priority Data
Feb. 19, 2014 (KR) 10-2014-0019120

(51) Int. Cl. H01L 29/66

(52) U.S. Cl. CPC H01L 29/66803; H01L 29/66492

(57) ABSTRACT

A method for fabricating a fin type transistor uniformly implants in targeted regions. The method includes forming a fin protruding in a Z-axis direction from a substrate positioned on an XY. A first region and a second region are included in the substrate and a gate is formed crossing the second region in X-axis direction. An implantation is performed on at least a portion of the second region. The fin is rotated through a first angle, another implantation is performed on at least a portion of the second region, and the fin is rotated again through a second angle, different from the first angle.

### CROSS-REFERENCE TO RELATED APPLICATION

This application claims priority from U.S. Provisional Application No. 61/920,871 filed on Dec. 26, 2013 in the United States Patent and Trademark Office and Korean Patent Application No. 10-2014-0019120 filed on Feb. 19, 2014 in the Korean Intellectual Property Office, and all the benefits accruing therefrom under 35 U.S.C. 119, the contents of which in its entirety are herein incorporated by reference.

### BACKGROUND

1. Field

Inventive concepts relate to a method for fabricating a fin type transistor, also referred to herein as a FinFET.

2. Description of the Related Art

As one of scaling techniques for increasing the density of integrated circuit devices, a multi-gate transistor has been proposed, in which a fin- or nanowire-shaped silicon body is formed on a substrate and a gate is then foamed on a surface of the silicon body.

Scaling of such a multi-gate transistor may be readily achieved because the multi-gate transistor uses a three-dimensional (3D) channel. In addition, current controlling capability may be improved even without increasing a gate length of the multi-gate transistor. Further, a short channel effect (SCE), whereby an electric potential of a channel region is affected by a drain voltage, can be effectively suppressed.

However, it is difficult to perform ion implantation, particularly, to achieve uniform implantation for a multi-gate transistor in which a 3D channel is formed in a small area. As a result, the 3D channel may not be properly formed.

### SUMMARY

In exemplary embodiments in accordance with principles of inventive concepts, a method for fabricating a fin type transistor includes forming a fin protruding from a substrate positioned on an XY plane in a Z-axis direction, extending in a Y-axis direction and including a first region and a second region; forming a first gate crossing the second region in an X-axis direction; performing a first implantation on at least a portion of the second region; rotating the fin and substrate through a first angle in the XY plane; performing a second ion implantation on at least a portion of the second region; and rotating the fin and substrate through a second angle in the XY plane different from the first angle.

In exemplary embodiments in accordance with principles of inventive concepts the first and second ion implantations include a halo ion implantation.

In exemplary embodiments in accordance with principles of inventive concepts a plurality of each of the first and second ion implantations are performed, and the first and second ion implantations are alternately performed.

In exemplary embodiments in accordance with principles of inventive concepts the fin is rotated a total of 360 degrees by performing the ion implantations.

In exemplary embodiments in accordance with principles of inventive concepts before performing the first ion implantation, the fin and substrate are rotated through a predetermined angle in the XY plane.

In exemplary embodiments in accordance with principles of inventive concepts the first and second ion implantations include first and second halo ion implantations on the fin wherein the fin is tilted in a YZ plane in a first scanning angle with regard to the implantation source.

In exemplary embodiments in accordance with principles of inventive concepts after the forming of the first gate, a first spacer is formed on the first gate sidewall and a lightly doped drain (LDD) region is formed on the first region.

In exemplary embodiments in accordance with principles of inventive concepts after the second ion implantation, a trench is formed by partially etching the first region and allowing a source/drain region to epitaxially grow in the trench.

In exemplary embodiments in accordance with principles of inventive concepts the source/drain region is spaced apart from the first region.

In exemplary embodiments in accordance with principles of inventive concepts after epitaxially growing the source/drain region, the first gate is replaced by the second gate.

In exemplary embodiments in accordance with principles of inventive concepts a method for fabricating a fin type transistor includes forming a gate on a fin protruding from a substrate, the gate crossing the fin; tilting the substrate; and performing a halo ion implantation on the fin positioned under the gate by rotating the substrate through first to nth rotation angles, where n is a natural number greater than or equal to 2, wherein the first to nth rotation angles are different.

In exemplary embodiments in accordance with principles of inventive concepts a method of fabricating a fin type transistor includes rotating a substrate through at least four rotations.

In exemplary embodiments in accordance with principles of inventive concepts the substrate is rotated a total of 360 degrees by the n rotations.

In exemplary embodiments in accordance with principles of inventive concepts LDD regions are formed on the exposed fin at opposite sides of the gate before performing the halo ion implantation process.

In exemplary embodiments in accordance with principles of inventive concepts a distance between regions on which the halo ion implantation process is performed is shorter than a distance between the LDD regions.

In exemplary embodiments in accordance with principles of inventive concepts a method of fabricating a fin type transistor includes implanting a substrate including a fin structure; and rotating the substrate after each implant, wherein no two sequential rotations are of equal angles.

In exemplary embodiments in accordance with principles of inventive concepts two non-sequential rotation angles are equal.

In exemplary embodiments in accordance with principles of inventive concepts the substrate is rotated through a predetermined angle before the first implant and the total angle of rotation, including the predetermined angle, is three hundred and sixty degrees.

In exemplary embodiments in accordance with principles of inventive concepts includes positioning the substrate at a tilt angle with respect to an implantation source before implanting.

In exemplary embodiments in accordance with principles of inventive concepts an implant is a halo implant.

### BRIEF DESCRIPTION OF THE DRAWINGS

The above and other features and advantages of inventive concepts will become more apparent by describing in detail exemplary embodiments thereof with reference to the attached drawings in which:

FIGS. 1 to 15 illustrate intermediate process steps of a method for fabricating a fin type transistor according to an exemplary embodiment of inventive concepts;

FIGS. 16 and 17 are a circuit view and a layout view illustrating a semiconductor device including a fin type transistor according to an exemplary embodiment of inventive concepts;

FIG. 18 is a block diagram of an electronic system including a fin type transistor according to an exemplary embodiment of inventive concepts; and

FIGS. 19 and 20 illustrate exemplary semiconductor systems to which semiconductor devices according to exemplary embodiments in accordance with principles of inventive concepts can be applied.

### DETAILED DESCRIPTION OF THE EMBODIMENTS

Various exemplary embodiments will be described more fully hereinafter with reference to the accompanying drawings, in which exemplary embodiments are shown. Exemplary embodiments may, however, be embodied in many different forms and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, for example, may be used herein to describe various elements, components, regions, layers and/or sections, these elements, components, regions, layers and/or sections should not be limited by these terms. These terms are only used to distinguish one element, component, region, layer or section from another region, layer or section. In this manner, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. In this manner, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

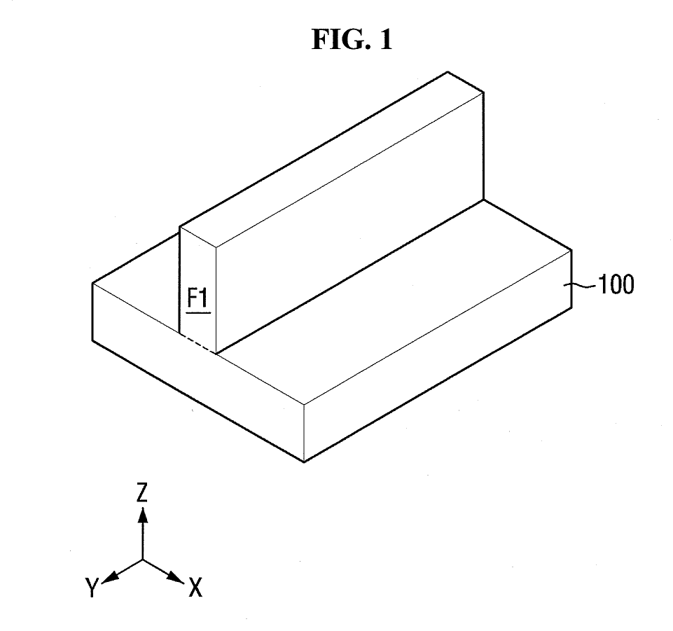

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. In this manner, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In this manner, the regions illustrated in the figures are schematic in nature and their shapes are not intended to illustrate the actual shape of a region of a device and are not intended to limit the scope of exemplary embodiments.
Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.
An exemplary embodiment of a method for fabricating a fin type transistor in accordance with principles of inventive concepts will be described with reference to FIGS. 1 to 15.

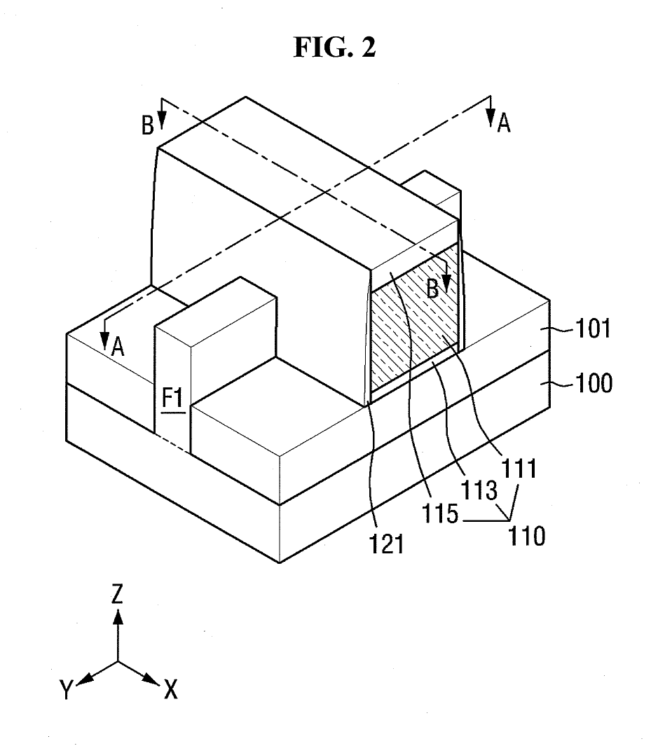

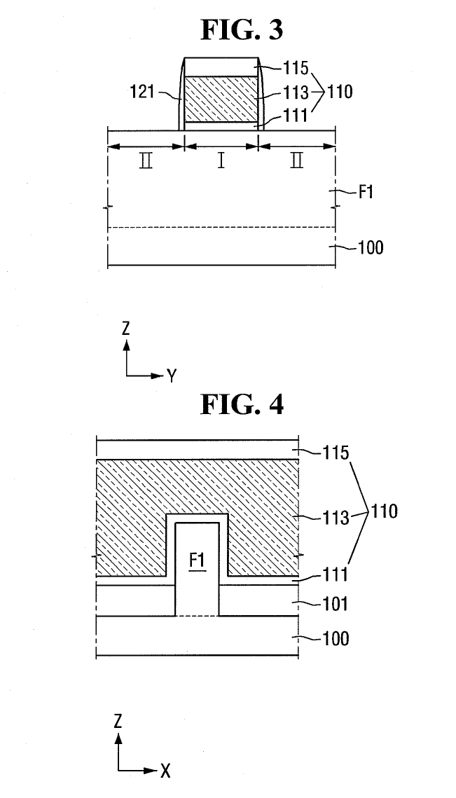

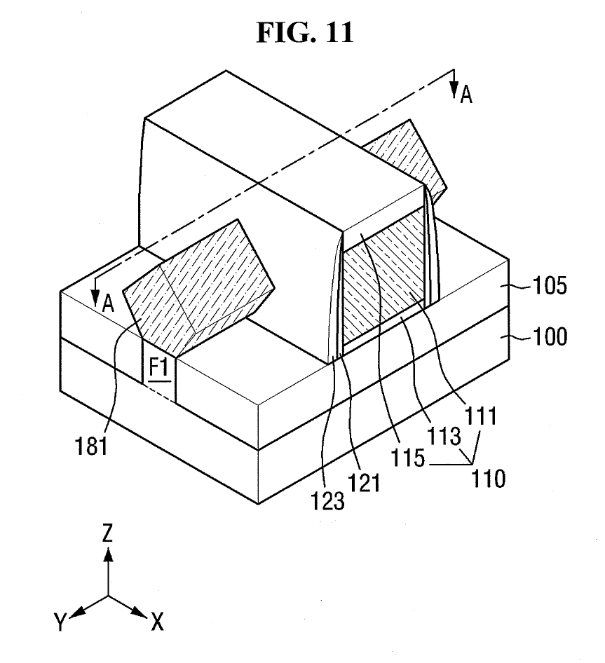

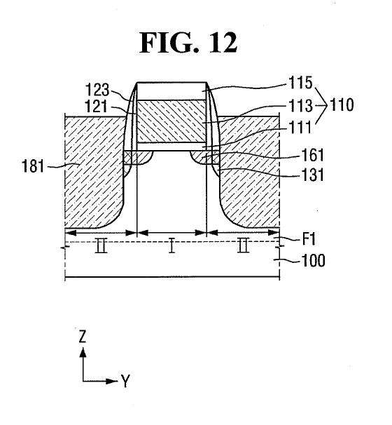

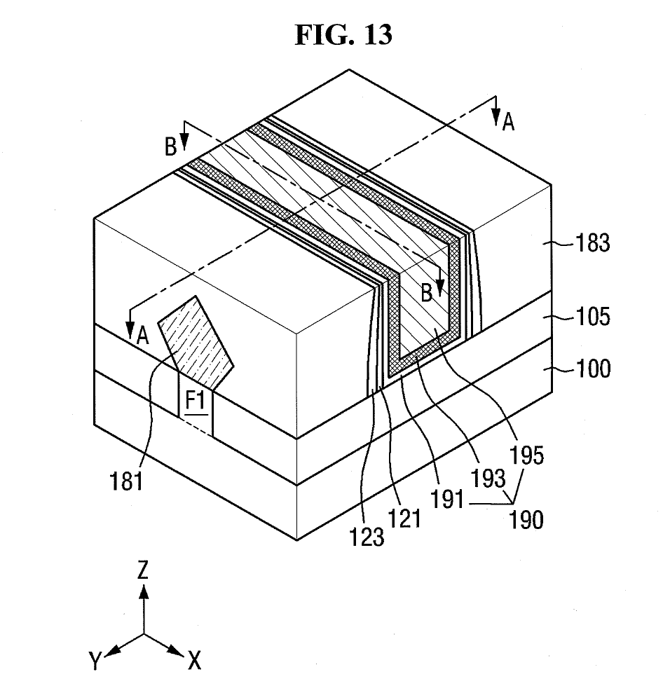

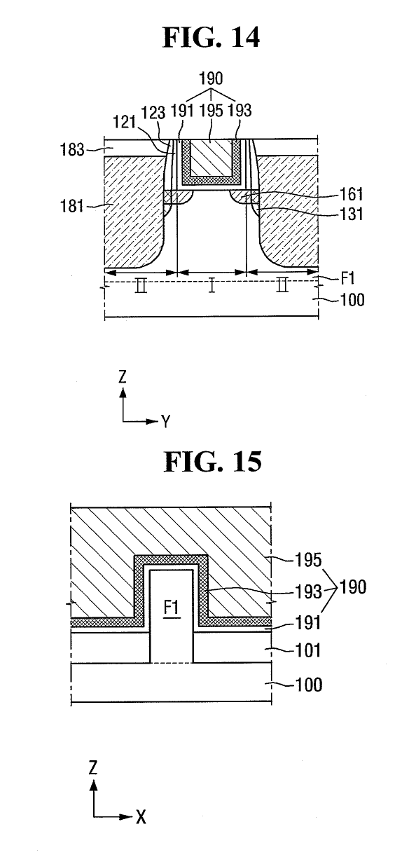

FIGS. 1 to 15 illustrate intermediate process steps of a method for fabricating a fin type transistor according to an exemplary embodiment in accordance with principles of inventive concepts. FIGS. 1, 2, 6, 7, 8, 11 and 13 are perspective views of the fin type transistor according to an exemplary embodiment in accordance with principles of inventive concepts, FIGS. 3 to 5, 9, 10, 12, 14 and 15 are cross-sectional views of the fin type transistor according to an exemplary embodiment in accordance with principles of inventive concepts. More particularly, FIG. 3 is a cross-sectional view taken along the line A-A of FIG. 2, FIG. 4 is a cross-sectional view taken along the line B-B of FIG. 2, FIG. 12 is a cross-sectional view taken along the line A-A of FIG. 11, FIG. 14 is a cross-sectional view taken along the line A-A of FIG. 13, and FIG. 15 is a cross-sectional view taken along the line B-B of FIG. 13.

Referring first to FIG. 1, in accordance with principles of inventive concepts, a fin F1 is foamed on a substrate 100. The substrate 100 may be positioned on an XY plane, and may include one or more semiconductor materials selected from the group consisting of Si, Ge, SiGe, GaP, GaAs, SiC, SiGeC, InAs and InP, for example. Substrate 100 may also be a silicon on insulator (SOI) substrate.

The fin F1 is formed on the substrate 100 and may protrude in a Z-axis direction. The fin F1 may extend lengthwise in a Y-axis direction, so that it may have long sides in the Y-axis direction and short sides in an X-axis direction, but aspects of inventive concepts are not limited thereto. For example, the long side direction could be the X-axis direction and the short side direction could be the Y-axis direction.

The fin F1 may be a portion of the substrate 100 and may include an epitaxial layer grown from the substrate 100 and may include, for example, Si or SiGe.

Referring to FIGS. 2 to 4, a first gate 110 crossing the fin F1 is formed on the fin F1. The fin F1 may include a first region □ and a second region □, with the first gate 110 positioned on the first region □ of the fin F1. Although this, in this exemplary embodiment, first gate 110 crosses the fin F1 at a right angle, that is, in the X-axis direction is illustrated in FIG. 2, inventive concepts are not limited thereto; first gate 110 may cross the fin F1 with an acute angle and/or obtuse angle formed with the Y-axis direction, for example.

Field insulation layer 101 may be formed on the substrate 100 and may be formed by stacking two or more insulation layers. In exemplary embodiments in accordance with principles of inventive concepts, field insulation layer 101 may cover bottom portions of sidewalls of the fin F1 while exposing top portions of the sidewalls of the fin F1.

The first gate 110 may include a first gate insulation layer 111, a first gate electrode 113, and a first hard mask layer 115. The first gate insulation layer 111, the first gate electrode 113 and the first hard mask layer 115 may be sequentially stacked.

The first gate insulation layer 111 may be conformally formed on a top surface of and top portions of side surfaces of the fin F1 and may be positioned between the first gate electrode 113 and the field insulation layer 101. The first gate insulation layer 111 may include silicon oxide or a high-k material having a higher dielectric constant than silicon oxide. For example, the first gate insulation layer 111 may include HfO₂, ZrO₂, LaO, Al₂O₃ or Ta₂O₅.

The first gate electrode 113 may be formed on the first gate insulation layer 111 and may include polysilicon, for example.

The first hard mask layer 115 may be formed on the first gate electrode 113 and may be made of a material including at least one of silicon oxide, silicon nitride and silicon oxynitride.

A first spacer 121 may be formed on sidewalls of the first gate 110. Before doping a lightly doped drain (LDD) region, the first spacer 121 may be formed for the purpose of protecting the first gate 110. The first spacer 121 may include, for example, SiN, and may be foamed by, for example, an atomic layer deposition (ALD) method.

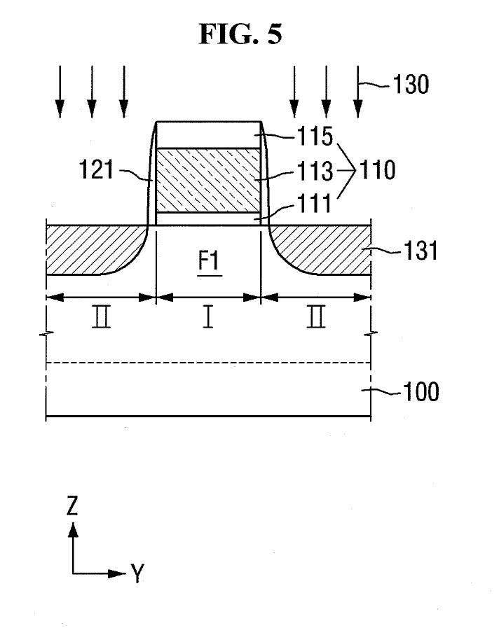

Referring to FIG. 5, LDD impurities are implanted (130) to form an LDD region 131 in the exposed fin F1. The LDD region 131 may be formed on the first spacer 121 and the second region □ of the fin F1, which is not covered by the first gate 110. The implanting 130 may be performed one time, for example.

The LDD impurities may be N type impurity or P type impurity. For example, the N type impurity may include As, and the P type impurity may include BF₂.

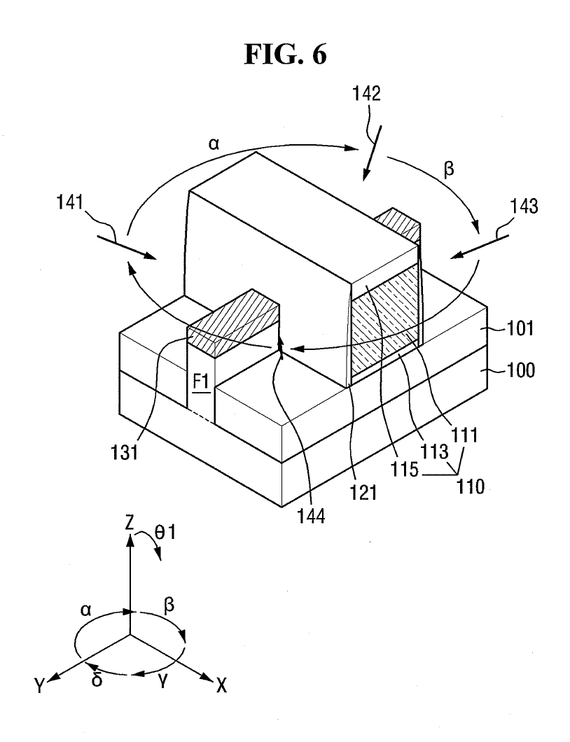

Referring to FIGS. 6 to 8, an ion implantation process is performed on first region I of the fin F1, which may be a channel region in which holes and/or electrons move. The ion implantation process may include a halo ion implantation process and impurities, such as BF₂, may be implanted, for example.

In order to uniformly implant impurities into the first region I, a plurality of ion implantations may be performed from different angles, in order to avoid shadow effects. When multiple implantations are performed, the fin F1 may be rotated on the XY plane through angles including first to nth rotation angles, where n is a natural number greater than or equal to 2. In exemplary embodiments in accordance with principles of inventive concepts, the rotation angles of the fin F1 need not be constant and the number “n” of rotation angles is equal to or smaller than the number of times the ion implantation processes (also referred to herein, simply, as “implantations”) are performed, which will now be described in more detail.

Referring to FIG. 6, an ion implantation process in accordance with principles of inventive concepts may include a first implantation 141, a second implantation 142, a third implantation 143 and a fourth implantation 144, for example. The first implantation 141 is performed; the substrate 100 (and fin F1) is rotated through the first rotation angle α; the second implantation is performed; the substrate 100 is rotated through the second rotation angle β; the third implantation 143 is performed; the substrate 100 is rotated through the third rotation angle γ; then, the fourth implantation 144 is performed, and the substrate 100 is rotated through the fourth rotation angle δ, returning the substrate to the original orientation, having rotated through a total of 360°.

In accordance with principles of inventive concepts, the first to fourth rotation angles α, β, γ and δ need not all be identical. That is, in accordance with principles of inventive concepts, rather than rotate the substrate 100 (and fin F1) through equal angles after each implantation, the substrate may be rotated at greater or lesser angles in order to achieve a uniform implantation, taking into account the geometry and structure (for example, avoiding shadowing) of the device being implanted. For example, in some exemplary embodiments in accordance with principles of inventive concepts, the first rotation angle α and the third rotation angle γ may be equal, and the second rotation angle β and the fourth rotation angle δ may be equal, without first and second (or third and fourth) rotation angles being equal. In such exemplary embodiments, the sum of the first to fourth rotation angles α, β, γ and δ may be 360 degrees.

If the ion implantation process were directly aligned with the direction of the Z-axis (perpendicular to XY plane, or, the bottom surface of substrate 100), first gate 110 and first spacer 121 would block impurities from reaching first region I. Therefore, in order to implant impurities into the first region I covered by the first gate 110, an ion implantation process in accordance with principles of inventive concepts may be performed with the substrate 100 and the fin F1 tilted by a first scanning angle θ1. For example, the ion implantation process may be performed with the substrate 100 (and fin F1) tilted on a YZ plane or a ZX plane by the first scanning angle θ1. It is contemplated within the scope of inventive concepts that an implantation source may be tilted with respect to the substrate by such an angle or the substrate may be tilted with respect to an implantation source by such an angle.

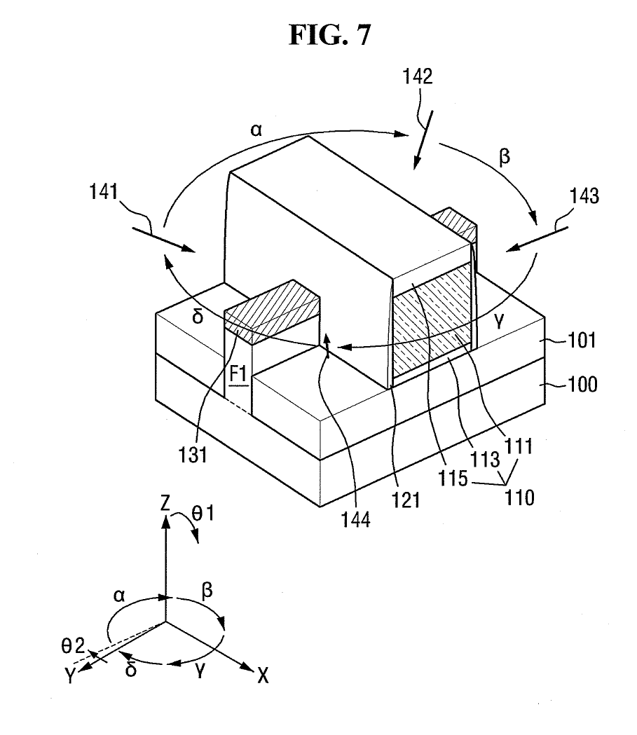

In exemplary embodiments in accordance with principles of inventive concepts, in order to efficiently implant impurities into the first region I substrate 100 (the bottom surface of which is coplanar with the XY plane) may be tilted by an angle θ2. Naturally, substrate 100 may be tilted by angle θ2 with respect to an implantation source or the implantation source may be tilted with respect to the substrate and this implantation step may be performed before the first ion implantation 141. As illustrated in the exemplary embodiment of FIG. 7, in order to implant impurities into the first region I ion implantation may be performed on a contact portion between the fin F1 and the first spacer 121. To this end, implantation may be performed as previously described, with implantations 141 through 144 performed using implantation α, β, γ, and δ, for example, in addition to tilt angles θ1 and/or θ2.

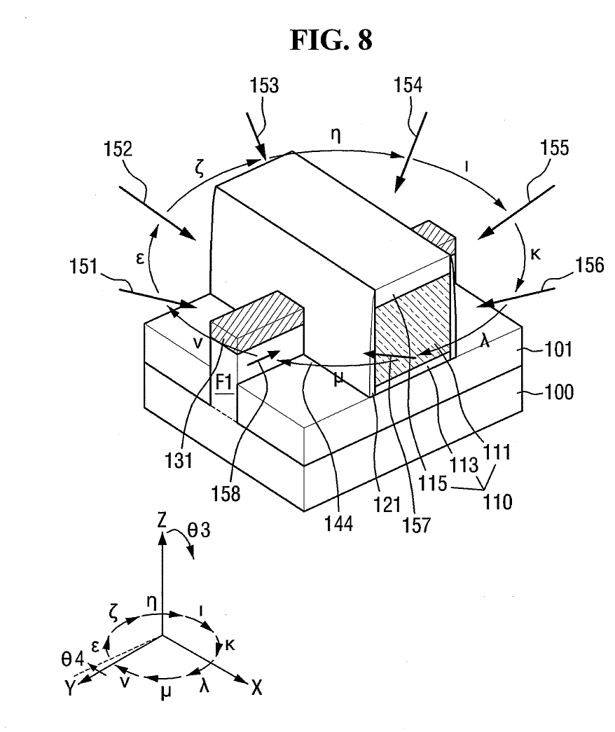

In exemplary embodiments in accordance with principles of inventive concepts as illustrated in FIG. 7, the first to fourth ion implantation processes 141 to 144 may be performed in the same manner as in FIG. 6, or ion implantation process may also be performed in a state in which the substrate 100 positioned on the XY plane is tilted on the YZ plane at the first scanning angle θ1, for example.
FIG. 8 illustrates another exemplary embodiment of an ion implantation process in accordance with principles of inventive concepts. In the exemplary embodiment of FIG. 8, eight implantations 151 to 158 are performed during the implantation process. In this exemplary embodiment, implantations 151, 152, 153, 154, 155, 156, 157, and 158 are respectively performed before rotations through angles ε, ζ, η, ι, κ, λ, μ and ν. In exemplary embodiments, some of the first to eighth rotation angles, ε, ζ, η, ι, κ, λ, μ and ν, may be equal to one another, but no two consecutive rotation angles are equal. In accordance with principles of inventive concepts ion implantations 151 to 158 may be performed in a state in which the fin F1 is tilted by a second scanning angle θ3 from the YZ plane. For example, before the first ion implantation 151 is performed, the substrate 100 may be rotated on the XY plane at a predetermined angle θ4, followed by performing the first ion implantation 151.

In exemplary embodiments in accordance with principles of inventive concepts, the substrate 110 and fin F1 associated therewith are returned to their original orientation at the completion of implantation process; the sum of the first to eighth rotation angles ε, ζ, η, ι, κ, λ, μ and ν may be 360 degrees. In exemplary embodiments in which the fin F1 (and substrate 100) is rotated at the predetermined angle θ4 before implantation commences, the sum of the predetermined angle θ4 and the first to eighth rotation angles ε, ζ, η, ι, κ, λ, μ and ν may be 360 degrees, resulting in the return of the fin F1 to its original, pre-rotation orientation.

In the exemplary embodiments in accordance with principles of inventive concepts described in the discussion related to FIGS. 6 to 8, the ion implantation process is performed 4 times or 8 times, but aspects of inventive concepts are not limited thereto. The ion implantation process may be performed at least 4 times in order to ensure that implantation is uniformly developed on the first region I.

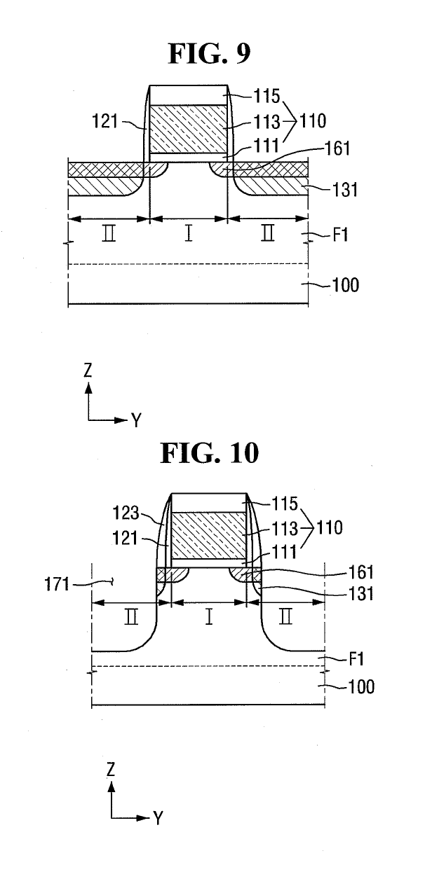

As shown in FIG. 9, impurities may be implanted into a portion of the first region □ disposed under the first gate 110 by performing ion implantation in accordance with principles of inventive concepts such as one of those described in the discussion related to FIGS. 6 to 8.

The impurities may be implanted into only a portion of the first region I, as shown in FIG. 9. Alternatively, the impurities may also be implanted into the entire portion of the first region I. As the result of the impurity implantation, ion implantation regions 161 are formed. The ion implantation regions 161 may be formed on the first region I and the second region II. A portion of the ion implantation regions 161 may overlap with the LDD region 131. Because the impurities are implanted into the first region I, a distance between the ion implantation regions 161 may be smaller than a distance between the LDD regions 131.

Referring to FIG. 10, a second spacer 123 may be formed on sidewalls of the first spacer 121. A width of the second spacer 123 may be greater than that of the first spacer 121. The second spacer 123 may be formed to preserve the LDD regions 131 or some of the ion implantation regions 161 in a subsequent process of forming a source/drain region (181 of FIG. 11), for example. The second spacer 123 may be made of the same material as the first spacer 121.

In exemplary embodiments in accordance with principles of inventive concepts, exposed fin F1 may be partially etched to form a trench 171. The trench 171 may be formed by partially etching a portion of fin F1 that is not covered by the first gate 110 and the first and second spacers 121 and 123, yielding a trench 171 formed on a portion of the second region II. The remaining LDD regions 131 and ion implantation regions 161 that are prevented by the second spacer 123 from being etched may have greater volumes than they would in embodiments in which the second spacer 123 is not formed.

Referring to FIGS. 11 and 12, in exemplary embodiments the source/drain region 181 is formed in the trench 171. The source/drain region 181 may be formed on the fin F1 and may be formed at opposite sides of the first gate 110. The source/drain region 181 may be an elevated source/drain. Therefore, a portion of the source/drain region 181 may be brought into contact with the second spacer 123. In addition, the source/drain region 181 and the first gate electrode 113 may be insulated from each other by the first and second spacers 121 and 123.

The source/drain region 181 may be spaced apart from the first region I by the first and second spacers 121 and 123, for example.

In embodiments in which the fin type transistor is a PMOS transistor, in accordance with principles of inventive concepts, the source/drain region 181 may include a compressive stress material. A compressive stress material may be a material having a larger lattice constant than silicon (Si), for example, SiGe. The compressive stress material may improve the mobility of carriers of a channel region by applying compressive stress to the fin F1. The source/drain region 181 may be formed through epitaxial growth.

In embodiments in which the fin type transistor is an NMOS transistor, in accordance with principles of inventive concepts, the source/drain region 181 may include the same material as the substrate 100 or a tensile stress material. For example, when the substrate 100 includes Si, the source/drain region 181 may include Si or a material having a smaller lattice constant than Si (for example, SiC).

In FIGS. 11 and 12, a top surface of the source/drain region 181 is positioned to be lower than a top surface of the first gate 110, but aspects of inventive concepts are not limited thereto. For example, the top surface of the source/drain region 181 may be positioned on the same plane as, or higher than, the top surface of the first gate 110.

Referring to FIGS. 13 to 15, in exemplary embodiments an interlayer insulation layer 183 covering the source/drain region 181 is formed on the resultant product of FIG. 11. The interlayer insulation layer 183 may include, for example, silicon oxide. Next, the interlayer insulation layer 183 is planarized to a top surface of the first gate electrode 113; the first hard mask layer 115 may be removed and the top surface of the first gate electrode 113 may be exposed.

Next, the first gate 110 may then be replaced by the second gate 190. To form the second gate 190, the first gate electrode 113 and the first gate insulation layer 111 of the first gate 110 are removed. As the first gate electrode 113 and the first gate insulation layer 111 are removed, the first region I of the fin F1 and a portion of the field insulation layer 101 may be exposed.

Next, the second gate 190 is formed in place of the first gate 110. The second gate 190 may include a second gate insulation layer 191, a first metal layer 193 and a second metal layer 195. The second gate insulation layer 191, the first metal layer 193 and the second metal layer 195 may be sequentially formed.

In exemplary embodiments second gate insulation layer 191 may include a high-k material having a higher dielectric constant than silicon oxide. For example, the second gate insulation layer 191 may include HfO₂, ZrO₂ or Ta₂O₅. The second gate insulation layer 191 may be conformally formed along the field insulation layer 101 and the sidewalls and top surface of the fin F1.

The first metal layer 193 may be formed on the second gate insulation layer 191. The first metal layer 193 may adjust a work function and may be conformally formed along the sidewalls and top surface of the fin F1. The first metal layer 193 may include, for example, at least one of TiN, TaN, TiC, and TaC.

The second metal layer 195 may be formed on the first metal layer 193 and may fill a space formed by the first metal layer 193. The second metal layer 195 may include, for example, W or Al. Alternatively, the first and second metal layers 193 and 195 may include Si or SiGe, rather than a metal.

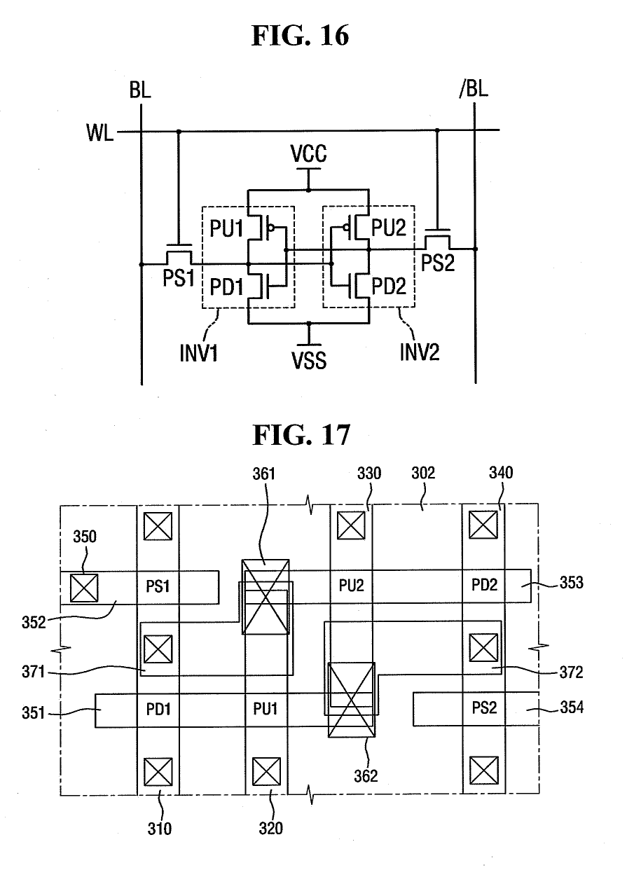

A semiconductor device in accordance with principles of inventive concepts, including a fin type transistor according to an embodiment of inventive concepts will be described with reference to FIGS. 16 and 17.

FIGS. 16 and 17 are, respectively, a circuit view and a layout view illustrating a semiconductor device including a fin type transistor in accordance with principles of inventive concepts. Although FIGS. 16 and 17 illustrate an SRAM by way of example, a fin type transistor fabricated by a method in accordance with principles of inventive concepts may be applied to other types of semiconductor devices.

Referring first to FIG. 16, the semiconductor device may include a pair of inverters INV1 and INV2 connected in parallel between a power supply node Vcc and a ground node Vss, and a first pass transistor PS1 and a second pass transistor PS2 connected to output nodes of the inverters INV1 and INV2. The first pass transistor PS1 and the second pass transistor PS2 may be connected to a bit line BL and a complementary bit line BL/. Gates of the first pass transistor PS1 and the second pass transistor PS2 may be connected to a word line WL.

The first inverter INV1 includes a first pull-up transistor PU1 and a first pull-down transistor PD1 connected in series to each other, and the second inverter INV2 includes a second pull-up transistor PU2 and a second pull-down transistor PD2 connected in series to each other. The first pull-up transistor PU1 and the second pull-up transistor PU2 may be PMOS transistors, and the first pull-down transistor PD1 and the second pull-down transistor PD2 may be NMOS transistors.

In addition, in order to constitute a latch circuit, an input node of the first inverter INV1 is connected to an output node of the second inverter INV2 and an input node of the second inverter INV2 is connected to an output node of the first inverter INV1.

Referring to FIGS. 16 and 17, in exemplary embodiments in accordance with principle of inventive concepts, a first fin 310, a second fin 320, a third fin 330 and a fourth fin 340, which are spaced apart from one another, may extend lengthwise in one direction (e.g., in an up-and-down direction of FIG. 17). The second fin 320 and the third fin 330 may extend in smaller lengths than the first fin 310 and the fourth fin 340.

In exemplary embodiments a first gate electrode 351, a second gate electrode 352, a third gate electrode 353, and a fourth gate electrode 354 are formed to extend in the other direction (for example, in a left-and-right direction of FIG. 17) to intersect the first fin 310 to the fourth fin 340. In exemplary embodiments, the first gate electrode 351 completely intersects the first fin 310 and the second fin 320 while partially overlapping with a terminal of the third fin 330. The third gate electrode 353 completely intersects the fourth fin 340 and the third fin 330 while partially overlapping with a terminal of the second fin 320. The second gate electrode 352 and the fourth gate electrode 354 are formed to intersect the first fin 310 and the fourth fin 340, respectively.

As shown, in exemplary embodiments, the first pull-up transistor PU1 is defined in vicinity of an intersection of the first gate electrode 351 and the second fin 320, the first pull-down transistor PD1 is defined in vicinity of an intersection of the first gate electrode 351 and the first fin 310, and the first pass transistor PS1 is defined in vicinity of an intersection of the second gate electrode 352 and the first fin 310. The second pull-up transistor PU2 is defined in vicinity of an intersection of the third gate electrode 353 and the third fin 330, the second pull-down transistor PD2 is defined in vicinity of an intersection of the third gate electrode 353 and the fourth fin 340, and the second pass transistor PS2 is defined in vicinity of an intersection of the fourth gate electrode 354 and the fourth fin 340.

Although not specifically shown, recesses may be formed at opposite sides of the respective intersections of the first to fourth gate electrodes 351-354 and the first to fourth fins 310, 320, 330 and 340, and sources/drains may be formed in the recesses and a plurality of contacts 250 may be formed.

A shared contact 361 concurrently connects the second fin 320, the third gate electrode 353 and a wire 371. A shared contact 362 may also concurrently connect the third fin 330, the first gate electrode 351 and a wire 372.

The first pull-up transistor PU1 and the second pull-up transistor PU2 may include fin type transistors fabricated by the method for fabricating a fin type transistor in accordance with principles of inventive concepts, such as shown in FIGS. 1 to 15.

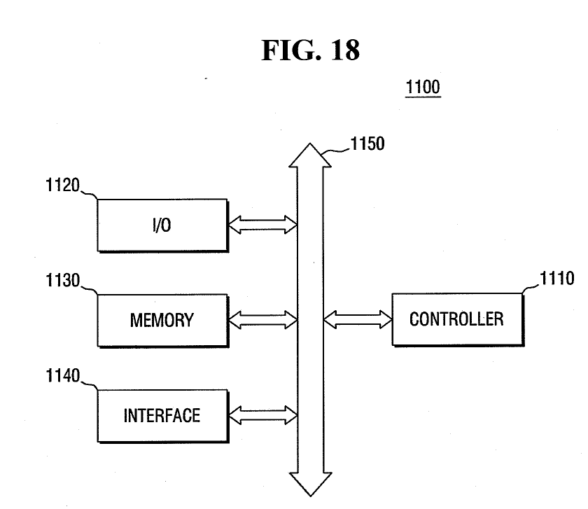

FIG. 18 is a block diagram of an electronic system including a fin type transistor in accordance with principles of inventive concepts.

Referring to FIG. 18, the electronic system 1100 may include a controller 1110, an input/output device (I/O) 1120, a memory device 1130, an interface 1140 and a bus 1150. The controller 1110, the I/O 1120, the memory device 1130, and/or the interface 1140 may be connected to each other through the bus 1150. The bus 1150 corresponds to a path through which data moves.

The controller 1110 may include at least one of a microprocessor, a digital signal processor, a microcontroller, and logic elements capable of functions similar to those of these elements. The I/O 1120 may include a keypad, a keyboard, a display device, and so on. The memory device 1130 may store data and/or commands. The interface 1140 may perform functions of transmitting data to a communication network or receiving data from the communication network. The interface 1140 may be wired or wireless. For example, the interface 1140 may include an antenna or a wired/wireless transceiver, and so on. Although not shown, the electronic system 1100 may further include high-speed DRAM and/or SRAM as a working memory for improving the operation of the controller 1110. A fin type transistor in accordance with principles of inventive concepts may be provided in the memory device 1130 or may be provided as some components of the controller 1110 or the I/O 1120, for example.

The electronic system 1100 may be applied to a personal digital assistant (PDA), a portable computer, a web tablet, a wireless phone, a mobile phone, a digital music player, a memory card, or any type of electronic device capable of transmitting and/or receiving information in a wireless environment.

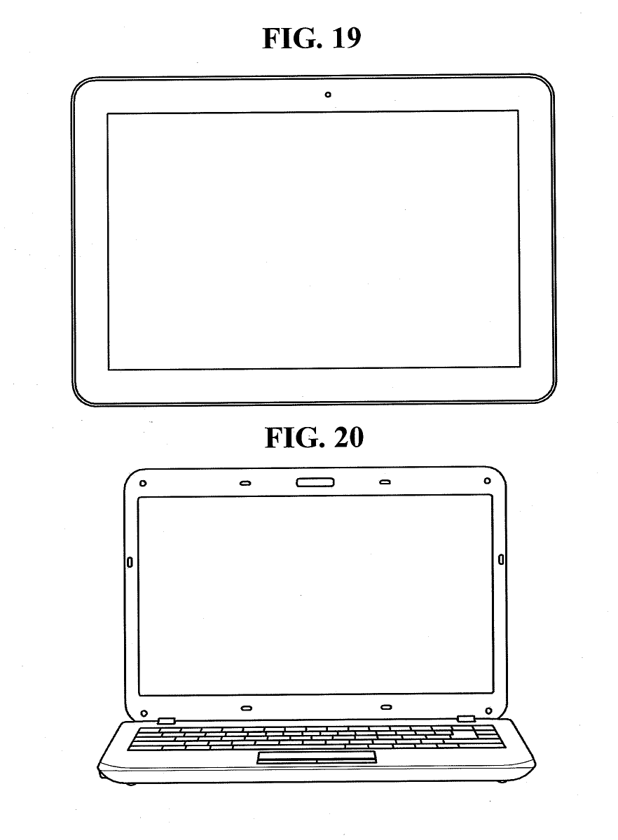

FIGS. 19 and 20 illustrate exemplary semiconductor systems to which semiconductor devices in accordance with principles of inventive concepts can be applied. FIG. 19 illustrates an example in which a semiconductor device in accordance with principles of inventive concepts is applied to a tablet PC, and FIG. 20 illustrates an example in which a semiconductor device in accordance with principles of inventive concepts is applied to a notebook computer. At least one of the fin type transistors in accordance with principles of inventive concepts can be employed to a tablet PC, a notebook computer, and the like. It should be apparent to one skilled in the art that the fin type transistor in accordance with principles of inventive concepts may also be applied to other electronic devices not illustrated herein.

While inventive concepts have been particularly shown and described with reference to exemplary embodiments thereof, it will be understood by those of ordinary skill in the art that various changes in form and details may be made therein without departing from the spirit and scope of inventive concepts as defined by the following claims. It is therefore desired that exemplary embodiments be considered in all respects as illustrative and not restrictive, reference being made to the appended claims rather than the foregoing description to indicate the scope of inventive concepts.

What is claimed is:

1. A method for fabricating a fin type transistor, the method comprising:
forming a fin protruding from a substrate positioned on an XY plane in a Z-axis direction, extending in a Y-axis direction and including a first region and a second region;
forming a first gate crossing the second region in an X-axis direction;
performing a first implantation on at least a portion of the second region;
rotating the fin and substrate through a first angle in the XY plane;
performing a second ion implantation on at least a portion of the second region; and
rotating the fin and substrate through a second angle in the XY plane different from the first angle.

2. The method of claim 1, wherein the first and second ion implantations include a halo ion implantation.

3. The method of claim 1, wherein a plurality of each of the first and second ion implantations are performed, and the first and second ion implantations are alternately performed.

4. The method of claim 3, wherein the fin is rotated a total of 360 degrees by performing the ion implantations.

5. The method of claim 1, wherein, before performing the first ion implantation, the fin and substrate are rotated through a predetermined angle in the XY plane.

6. The method of claim 1, wherein the first and second ion implantations include first and second halo ion implantations on the fin wherein the fin is tilted in a YZ plane in a first scanning angle with regard to the implantation source.

7. The method of claim 1, wherein, after the forming of the first gate, a first spacer is formed on the first gate sidewall and a lightly doped drain (LDD) region is formed on the first region.

8. The method of claim 1, wherein, after the second ion implantation, a trench is formed by partially etching the first region and allowing a source/drain region to epitaxially grow in the trench.

9. The method of claim 8, wherein the source/drain region is spaced apart from the first region.

10. The method of claim 8, wherein, after epitaxially growing the source/drain region, the first gate is replaced by the second gate.

11. A method for fabricating a fin type transistor, comprising:
forming a gate on a fin protruding from a substrate, the gate crossing the fin;
tilting the substrate; and
performing a halo ion implantation on the fin positioned under the gate by rotating the substrate through first to nth rotation angles, where n is a natural number greater than or equal to 2, wherein the first to nth rotation angles are different.

12. The method of claim 11, wherein n is at least 4.

13. The method of claim 11, wherein the substrate is rotated a total of 360 degrees by the n rotations.

14. The method of claim 11, wherein LDD regions are formed on the exposed fin at opposite sides of the gate before performing the halo ion implantation process.

15. The method of claim 14, wherein a distance between regions on which the halo ion implantation process is performed is shorter than a distance between the LDD regions.

16. A method of fabricating a fin type transistor, comprising:
implanting a substrate including a fin structure; and
rotating the substrate after each implant, wherein no two sequential rotations are of equal angles.

17. The method of claim 16, wherein two non-sequential rotation angles are equal.

18. The method of claim 16, wherein the substrate is rotated through a predetermined angle before the first implant and the total angle of rotation, including the predetermined angle, is three hundred and sixty degrees.

19. The method of claim 16, further comprising positioning the substrate at a tilt angle with respect to an implantation source before implanting.

20. The method of claim 16, wherein an implant is a halo implant.
